(19) United States
(12) Patent Application Publication
(10) Pub. No.: US 2017/0110600 A1
(43) Pub. Date: Apr. 20, 2017

(54) METHOD OF MANUFACTURING PHOTOVOLTAIC DEVICE HAVING ULTRA-SHALLOW JUNCTION LAYER

(71) Applicant: NATIONAL CENTRAL UNIVERSITY, Taoyuan City (TW)

(72) Inventors: Jenq-Yang CHANG, Taoyuan City (TW); Chien-Chieh LEE, Taoyuan City (TW); Ting-Tung LI, Taoyuan City (TW); Yen-Ho CHU, Taoyuan City (TW); Teng-Hsiang CHANG, Taoyuan City (TW); Shih-Hung WANG, Hsinchu City (TW)

(21) Appl. No.: 14/883,347

(22) Filed: Oct. 14, 2015

(51) Int. Cl. H01L 31/0216; H01L 31/0224; H01L 31/068; H01L 31/18

(52) U.S. Cl. CPC H01L 31/02168; H01L 31/1804; H01L 31/1864; H01L 31/1884; H01L 31/022483; H01L 31/022466; H01L 31/022475; H01L 31/068

(57) ABSTRACT

The present invention relates to a method of manufacturing a photovoltaic device having an ultra-shallow junction layer. In the method, a crystalline silicon substrate is cleaned and a first doped semiconductor layer with 1.12 eV bandgap and 5˜80 nm of thickness is grown on the crystalline silicon substrate by high density plasma electron cyclotron resonance CVD in a preparation condition of a temperature of the crystalline silicon substrate ranging from 50° C. to 250° C. , about 500W of microwave power, deposition pressure below 50 mTorr, about 20 sccm of argon and hydrogen flow rate, SiH₄ flow rate ranging from 1 sccm to 2 sccm, and 2% boroethane flow rate ranging from about 5 seem to 15 sccm. The photovoltaic device of the present invention has advantages of abrupt homo-junction, ultra-thin high-crystallinity silicon-based thin film, highly-doped concentration, high conductivity and high short-circuit current, thereby having improved efficiency.

### BACKGROUND

1. Technical Field

The present invention relates to a method of manufacturing a photovoltaic device having an ultra-shallow junction layer, more particularly to a method of growing a first doped semiconductor layer with about 1.12 eV of bandgap and a thickness ranging from 5 nm to 80 nm by using a high density plasma electron cyclotron resonance CVD manner under a preparation condition, so as to improve an efficiency of the photovoltaic device.

2. Description of Related Art

With gradual exhaustion of existing energies (such as oil and coal), how to develop an alternative energy to replace the existing energies gradually attracts more attention. Among the alternative energies, the solar energy is plentiful and does not cause environmental pollution, so the solar cell becomes the focus of people's attention. The solar cell is a photovoltaic conversion device capable of converting light energy into electric energy, and a single-junction solar cell is a kind of solar cell having a the simplest structure. As shown in FIG. 7, the single junction solar cell includes a silicon substrate A, and a first electrode A1, a P-type semiconductor layer A2, an intrinsic layer A3, an N-type semiconductor layer A4, a second electrode A5 and a passivation and anti-reflection layer formed sequentially on a side of the silicon substrate A. When sunlight irradiates on and passes through the passivation and anti-reflection layer A6 and the P-type semiconductor layer A2, the silicon substrate A absorbs the light energy to generate free electrons and holes. The electrons and holes are respectively moved towards the P-type semiconductor layer A2 and the N-type semiconductor layer A4 subject to a built-in potential, so that a current is generated and flows out of the electrode to form the electrical energy for usage or storage.

Theoretically, a solar cell emitter formed by a shallow silicon-based thin film with thickness smaller than 200 nm, can reduce the absorption of the emitter and inhibit recombination of the minority carriers, thereby rising efficiency of the solar cell. Currently, most methods of manufacturing the shallow layer silicon-based thin film as the solar cell emitter must be performed by a specific CVD (chemical vapor deposition) system under a higher temperature (slightly higher than 300° C.), or a traditional high-temperature diffusion doping process. However, these methods require higher manufacturing temperature, longer manufacturing time, and even more complicated process and higher cost, so their applications in industry are limited.

### SUMMARY

The first objective of the present invention is that a first doped semiconductor layer having a thickness ranging from 5 nm to 80 nm and about 1.12 eV of bandgap is grown on a crystalline silicon substrate by the high density plasma electron cyclotron resonance CVD (ECR-CVD) under a preparation condition, and an ultra-shallow (lower than 30 nm) silicon-based epitaxy homo-junction is grown on a texture silicon wafer and manufactured under a low process temperature (lower than 200° C.), so that the manufacturing time can be shortened and the device c-Si solar cell has the advantage of abrupt epitaxy homo-junction. The silicon-based thin film with high crystallinity can efficiently have an extremely thin thickness ranging from 20 nm to 100 nm, highly-doped concentration and high conductivity, and the photovoltaic device having ultra-shallow junction layer has the short-circuit current density larger than or equal to 40 mA/cm², so the method of the present invention can manufacture high-efficiency ultra-thin silicon photovoltaic device , and reduce costs of the silicon material and power consumption of heat treatment, and directly combine with the existing industrialized silicon solar cell production.

The second objective of the present invention is that, during the high density plasma generated by electron cyclotron resonance, the temperature of the crystalline silicon substrate ranges from 50° C. to 250° C., the better one ranges from 100° C. to 230° C., the preferred one ranges from 120° .C to 210° C., and the optimal one ranges from 140° C. to 200° C.

The third objective of the present invention is that, during the high density plasma generated by electron cyclotron resonance, the deposition pressure is below 50 mTorr, the better one ranges from 1 mTorr to 30 mTorr, the preferred one ranges from 5 mTorr to 25 mTorr, the optimal one ranges from 10 mTorr to 20 mTorr.

The fourth objective of the present invention is that, during the high density plasma generated by electron cyclotron resonance, the gas doping ratio of H₂:B₂H₆ is 10˜60:10˜50, and the better one is 20˜40:30˜50.

The fifth objective of the present invention is that the thickness of the first doped semiconductor layer ranges from 5 nm to 80 nm, the better one ranges from 5 nm to 50 nm, and the preferred one ranges from 10 nm to 35 nm.

The sixth objective of the present invention is that the first doped semiconductor layer is an N-type or P-type doped epitaxy back surface field (BSF) layer.

The seventh objective of the present invention is that the first anti-reflection layer is formed on the first doped semiconductor layer, or the first anti-reflection layer and the second anti-reflection layer are respectively formed on surfaces of the first doped semiconductor layer and the second doped semiconductor layer, and a main function of the anti-reflection layer is to decrease the ratio of the reflected light and the ratio of the incident light after being irradiated by sunlight, so as to improve sunlight utilization efficiency and further improve the photoelectric conversion efficiency of the photovoltaic device.

The eighth objective of the present invention is that, after the first electrode is formed or the first and second electrodes are formed, the rapid thermal annealing (RTA) is performed, thereby stabilizing the sizes and consistency of dice and further improving photocurrent absorption efficiency of device.

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a flow chart of steps of the present invention.

FIG. 2 is a sectional view of a first embodiment of the present invention.

FIG. 3 is a sectional view of a second embodiment of the present invention.

FIG. 4 is a flow chart of other steps of the present invention.

FIG. 5 is a sectional view of a third embodiment of present invention.

FIG. 6 is a sectional view of a fourth embodiment of the present invention.

FIG. 7 is a sectional view of a traditional solar cell.

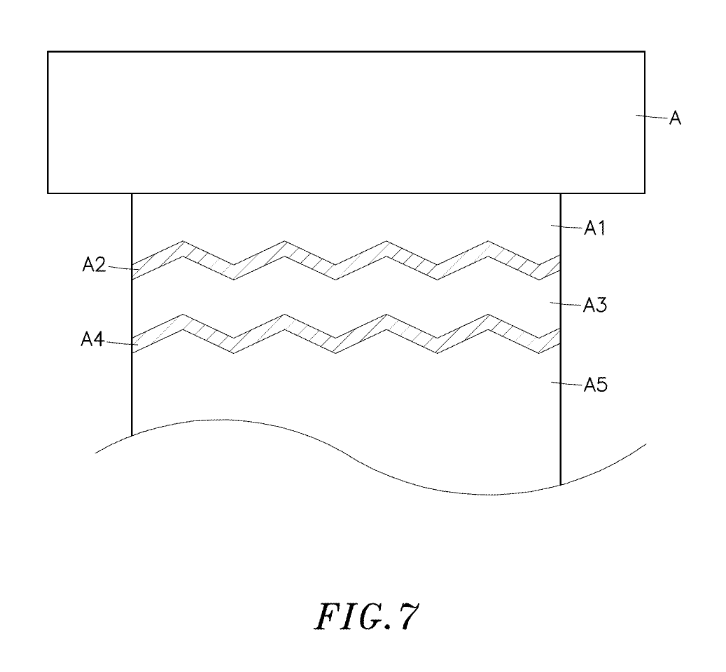

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

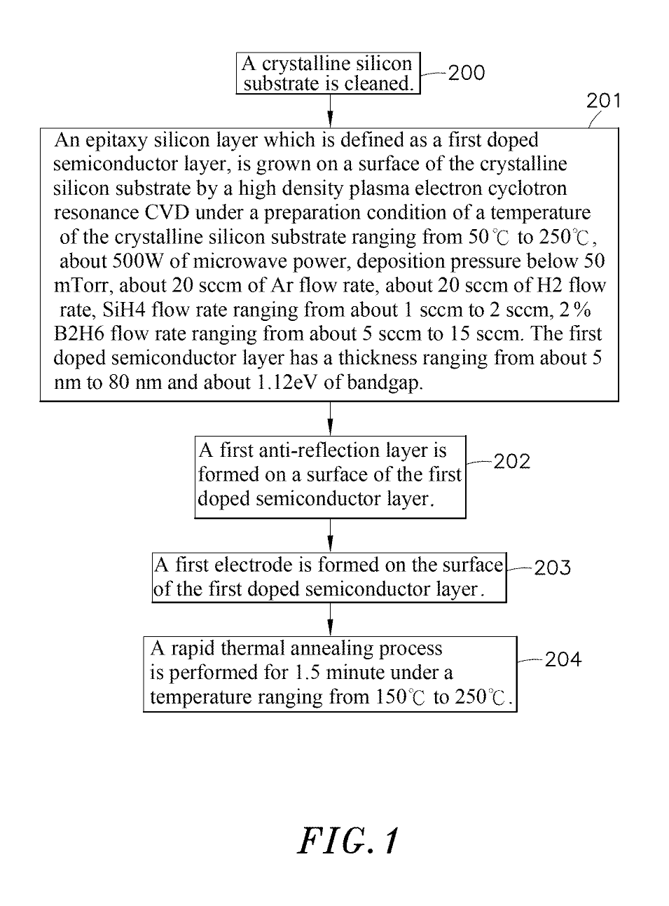

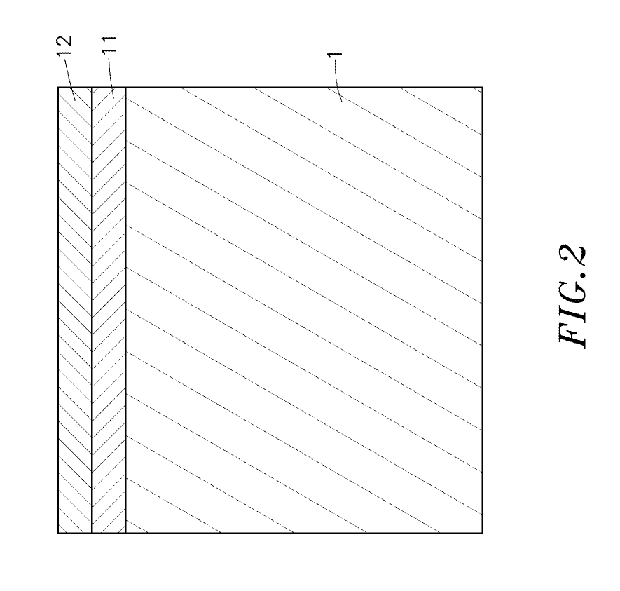

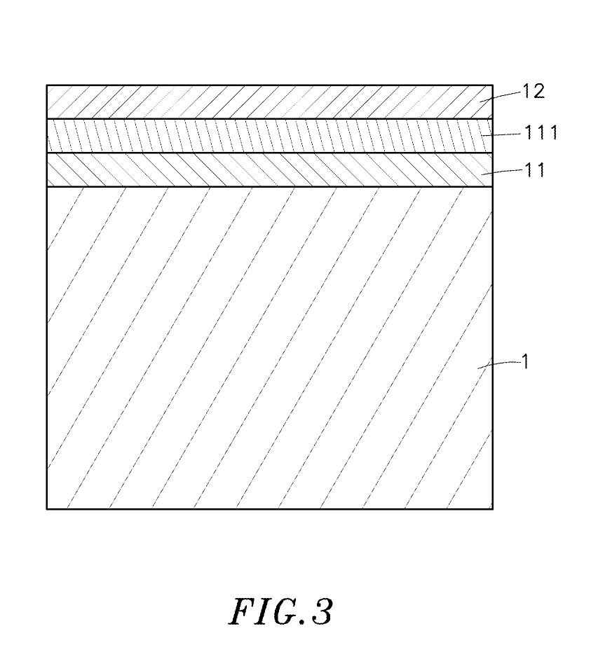

Please refer to FIGS. 1-3. The manufacturing method includes following steps.

In step (200), a crystalline silicon substrate 1 is cleaned.

In step (201), an epitaxy silicon layer which is defined as a first doped semiconductor layer 11, is grown on a surface of the crystalline silicon substrate 1 by a high density plasma electron cyclotron resonance CVD under a preparation condition of a temperature of the crystalline silicon substrate 1 ranging from 50° C. to 250° C., about 500 W of microwave power, deposition pressure below 50 mTorr, about 20 sccm of Ar flow rate, about 20 sccm of H₂ flow rate, SᵢH₄ flow rate ranging from about 1 sccm to 2 sccm, 2% B₂H₆ flow rate ranging from about 5 sccm to 15 sccm. The first doped semiconductor layer 11 has a thickness ranging from about 5 nm to 80 nm and about 1.12 eV of bandgap. The term “sccm” is abbreviation of standard cubic centimeter per minute.

In step (202), a first anti-reflection layer 111 is formed on a surface of the first doped semiconductor layer 11.

In step (203), a first electrode 12 is formed on the surface of the first doped semiconductor layer 11.

In step (204), a rapid thermal annealing process is performed for 1.5 minute under a temperature ranging from 150° C. to 250° C.

The above-mentioned steps are flows of manufacturing single-junction photovoltaic device, and after the step (201) of growing the epitaxy silicon layer as the first doped semiconductor layer 11, the step (202) can be performed to form the first anti-reflection layer 111 and then perform the step (203); alternatively, the step (202) can be omitted and the step (203) can be performed directly. In addition, after the step (203) of forming the first electrode 12, the step (204) of the rapid thermal annealing process can be performed; alternatively, the step (204) can be omitted.

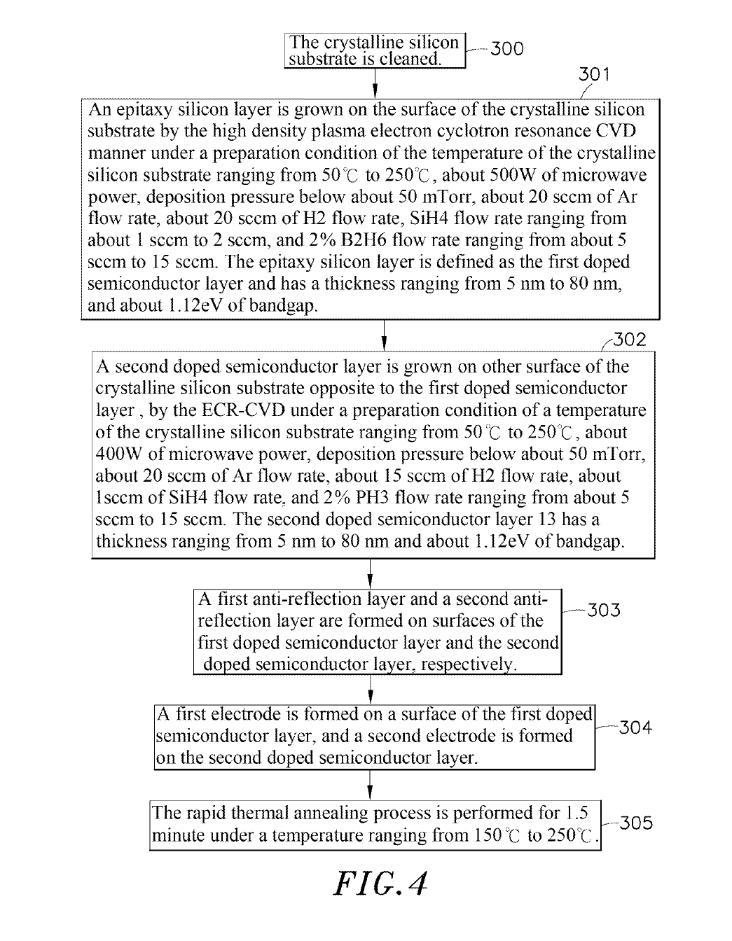

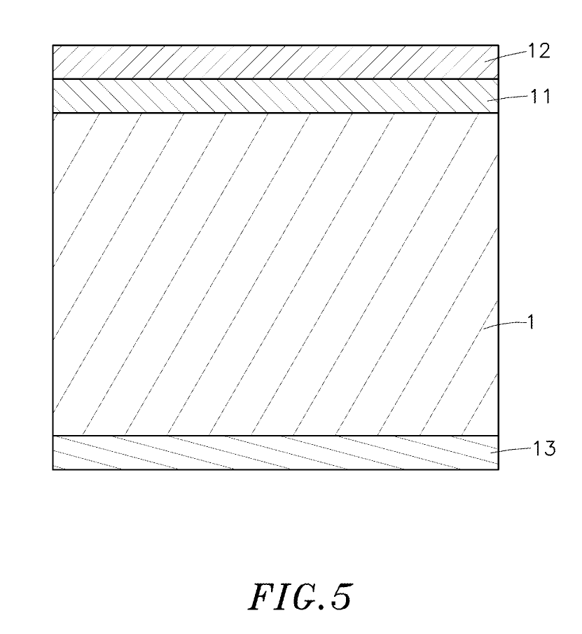

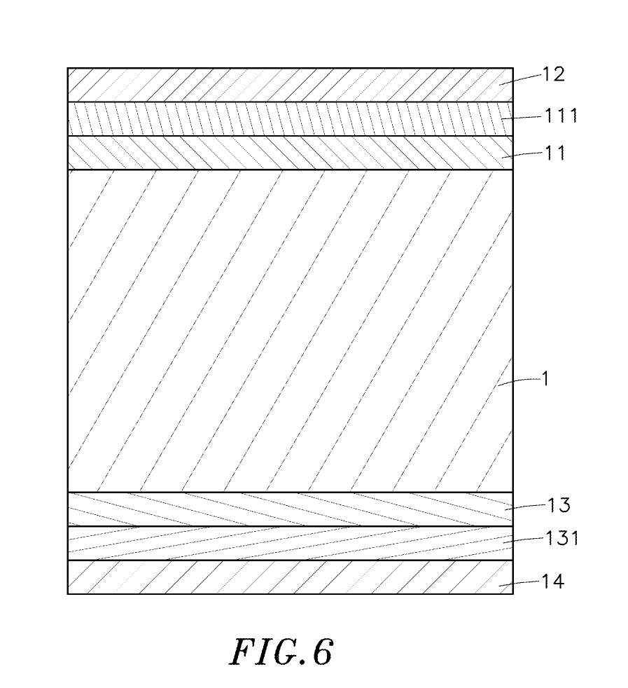

Please refer to FIGS. 1-6. The method includes following steps shown in the Figs clearly.

In step (300), the crystalline silicon substrate 1 is cleaned.

In step (301), an epitaxy silicon layer is grown on the surface of the crystalline silicon substrate 1 by the high density plasma electron cyclotron resonance CVD manner under a preparation condition of the temperature of the crystalline silicon substrate 1 ranging from 50° C. to 250° C., about 500 W of microwave power, deposition pressure below about 50 mTorr, about 20 sccm of Ar flow rate, about 20 sccm of H₂ flow rate, SiH₄ flow rate ranging from about 1 sccm to 2 seem, and 2% B₂H₆ flow rate ranging from about 5 sccm to 15 sccm. The epitaxy silicon layer is defined as the first doped semiconductor layer 11 and has a thickness ranging from 5 nm to 80 nm, and about 1.12 eV of bandgap.

In step (302), a second doped semiconductor layer 13 is grown on other surface of the crystalline silicon substrate 1 opposite to the first doped semiconductor layer 11, by the ECR-CVD under a preparation condition of a temperature of the crystalline silicon substrate 1 ranging from 50° C. to 250° C., about 400 W of microwave power, deposition pressure below about 50 mTorr, about 20 sccm of Ar flow rate, about 15 sccm of H₂ flow rate, about 1 sccm of SiH₄ flow rate, and 2% PH₃ flow rate ranging from about 5 sccm to 15 sccm. The second doped semiconductor layer 13 has a thickness ranging from 5 nm to 80 nm and about 1.12 eV of bandgap.

In step (303), a first anti-reflection layer 111 and a second anti-reflection layer 131 are formed on surfaces of the first doped semiconductor layer 11 and the second doped semiconductor layer 13, respectively.

In step (304), a first electrode 12 is formed on a surface of the first doped semiconductor layer 11, and a second electrode 14 is formed on the second doped semiconductor layer 13.

In step (305), the rapid thermal annealing process is performed for 1.5 minute under a temperature ranging from 150° C. to 250° C.

The above-mentioned steps are flows of manufacturing a dual-junction photovoltaic device, and after the step (302) of growing the epitaxy silicon layer as the second doped semiconductor layer 13, the step (303) can be performed to form the first anti-reflection layer 111 and the second anti-reflection layer 131 and the step (304) is then performed. After the step (304) of forming the first electrode 12 and the second electrode 14, the step (305) of rapid thermal annealing process can be performed; alternatively, the step (305) can be omitted.

In following embodiment, the first doped semiconductor layer 11 is grown by using the high density plasma electron cyclotron resonance CVD, and the first doped semiconductor layer 11 is a P-type epitaxy silicon layer and its preparation condition contains 160° C. of temperature of the crystalline silicon substrate 1, about 500 W of microwave power, about 20 mTorr of deposition pressure, about 20 sccm of Ar flow rate, about 20 sccm of H₂ flow rate, SiH₄ flow rate ranging from about 1 sccm to 2 sccm, and 2% B₂H₆ flow rate ranging from about 5 sccm to 15 sccm, and the first doped semiconductor layer 11 has about 20 nm of thickness and about 1.12 eV of bandgap. When the dual-junction photovoltaic device is manufactured, the second doped semiconductor layer 13 is further grown by using the high density plasma electron cyclotron resonance CVD , the second doped semiconductor layer 13 is N-type epitaxy silicon layer and its preparation condition contains 200° C. of temperature of the crystalline silicon substrate 1, about 400 W of microwave power, about 20 mTorr of deposition pressure, about 20 sccm of Ar flow rate, about 15 sccm of H2 flow rate, about 1 sccm of SiH₄ flow rate and 2% PH₃ flow rate ranging from about 5 sccm to 15 sccm. The second doped semiconductor layer 13 has about 300 Å of thickness and about 1.12 eV of bandgap.

The photovoltaic device manufactured by the above-mentioned steps and having the ultra-shallow junction layer, is tested by a solar simulator under AM 1.5 of sunlight intensity, to obtain photovoltaic conversion characteristics thereof. The obtained short-circuit current is 32.98 mA/cm² (aperture area), the obtained efficiency is 11.5%. The thickness of the thin film is measured by an alpha-step apparatus, type veeco dektak 6M. A Raman imaging microscope system 1000, manufactured by the RENISHAW Corporation, is operated to qualitatively analyze quality of crystallinity and bonding between atoms.

In the photovoltaic device manufactured by the method of present invention, an ultra-shallow (lower than 30 nm) silicon-based epitaxy homo-junction is grown on a surface of the textured silicon wafer and manufactured under a low process temperature (lower than 200° C.), so that the manufacturing time can be shortened and the c-Si solar cell has the advantage of abrupt epitaxy homo-junction. The silicon-based thin film with high-crystallinity can effectively have an extremely thin thickness (20˜100 nm), highly-doped concentration and high conductivity. Because the absorption of the emitter layer is reduced and recombination of minority carriers is inhibited, the photovoltaic device having the ultra-shallow junction layer can have higher short-circuit current (larger than or equal to 40 mA/cm²), and the efficiency of product is improved consequently.

Further, the photovoltaic device having the ultra-shallow junction layer can be combined with texture structure to enhance the light-harvesting effect for obtaining high short-circuit current density (such as Jsc larger than or equal to 40 mA/cm²). In addition, the high-quality homo epitaxy doped layer is grown on a silicon wafer with low cost under low-temperature environment for manufacturing the high-efficiency ultra-thin silicon photovoltaic device, so costs of the silicon material and power consumption of the heat treatment can be reduced, and this method can replace traditional high-temperature diffusion doping and directly combine with the existing industrialized silicon solar cell production.

The first anti-reflection layer 111 and second anti-reflection layer 131 formed in above-mentioned flows are mainly to reduce the ratio of reflected light and increase the ratio of incident light under irradiation of sunlight, so as to improve sunlight utilization efficiency and further improve the photoelectric conversion efficiency of the photovoltaic device. The rapid thermal annealing process can stabilize the sizes and consistency of dice, so as to improve photocurrent absorption efficiency of device.

During operation of the high density plasma electron cyclotron resonance CVD, the temperature of the crystalline silicon substrate 1 can ranges from 50° C. to 250° C.; and the better one ranges from 100° C. to 230° C.; and the preferred one ranges from 120° C. to 210° C.; and the optimal one ranges from 140° C. to 200° C.

During operation of the high density plasma electron cyclotron resonance CVD manner, the deposition pressure is below 50 mTorr, the better one ranges from 1 mTorr to 30 mTorr, the preferred one ranges from 5 mTorr to 25 mTorr, and the optimal one ranges from 10 mTorr to 20 mTorr.

During operation of the high density plasma electron cyclotron resonance CVD manner, the gas doping ratio of H₂:B3₂H₆ is 10˜60:10˜50; and the preferred one is 20˜40:30˜50.

The thickness of the first doped semiconductor layer 11 ranges from 5 nm to 80 nm, the better one ranges from 5 nm to 50 nm, and the preferred one ranges from 10 nm to 35 nm.

There is no specific limitation for the first doped semiconductor layer 11, and preferably, the first doped semiconductor layer 11 is N-type or P-type doped epitaxy back surface field (BSF) layer.

The first electrode 12 and the second electrode 14 can be transparent conductive layers, and preferably, the transparent conductive layer is a zinc oxide layer, tin oxide layer or indium tin oxide (ITO) layer. Optimally, the transparent conductive layer is the ITO layer. Alternatively, the first electrode 12 and the second electrode 14 can be metal conductive layers, and preferably, the metal conductive layer is a titanium silver layer or an aluminum layer. The first electrode 12 and the second electrode 14 can include transparent conductive layers and metal conductive layers plated sequentially.

The substrate can be a transparent substrate (such as glass substrate, plastic substrate and so on) or non-transparent substrate (such as stainless steel substrate, metal plate and so on).

It should be noted that various equivalent changes, alternations or modifications based on the above-mentioned embodiments are all consequently viewed as being embraced by the scope of the present disclosure.

Therefore, the present invention is mainly directed to the method of manufacturing the photovoltaic device having the ultra-shallow junction layer, and in the method, the crystalline silicon substrate is cleaned and the first doped semiconductor layer with 1.12 eV of bandgap and a thickness ranging from 5 nm to 80 nm is then grown on the cleaned crystalline silicon substrate by the high density plasma electron cyclotron resonance CVD under the preparation condition. The photovoltaic device has advantages of abrupt epitaxy homo-junction, ultra-thin high crystallinity silicon-based thin film, highly-doped concentration, high conductivity and high short-circuit current, thereby having improved efficiency.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A method of manufacturing a photovoltaic device having an ultra-shallow junction layer, comprising:
step (a00): cleaning a crystalline silicon substrate;
step (a01): growing an epitaxy silicon layer on a surface of the crystalline silicon substrate by using a high density plasma electron cyclotron resonance CVD under a preparation condition of a temperature of the crystalline silicon substrate ranging from 50° C. to 250° C., about 500 W of microwave power, deposition pressure below 50 mTorr, about 20 sccm of argon flow rate, about 20 sccm of hydrogen flow rate, SiH₄ flow rate ranging from 1 sccm to 2 sccm and 2% boroethane flow rate ranging from about 5 sccm to 15 sccm, wherein the epitaxy silicon layer is defined as a first doped semiconductor layer and has a thickness ranging from 5 nm to 80 nm and about 1.12 eV of bandgap; and
step (a02): forming a first electrode on a surface of the first doped semiconductor layer.

2. The method according to claim 1, wherein after the step (a01) of growing the first doped semiconductor layer and prior to the step (a02), a first anti-reflection layer is formed on the first doped semiconductor layer.

3. The method according to claim 1, wherein after the step (a02) is completed, a rapid thermal annealing (RTA) is performed for 1.5 minute under a temperature ranging from 150° C. to 250° C. .

4. The method according to claim 1, wherein during operation of the high density plasma electron cyclotron resonance CVD manner, the temperature of the crystalline silicon substrate ranges from 100° C. to 230° C.

5. The method according to claim 4, wherein during operation of the high density plasma electron cyclotron resonance CVD manner, the temperature of the crystalline silicon substrate ranges from 120° C. to 210° C.

6. The method according to claim 5, wherein during operation of the high density plasma electron cyclotron resonance CVD manner, the temperature of the crystalline silicon substrate ranges from 140° C. to 200° C.

7. The method according to claim 1, wherein during operation of the high density plasma electron cyclotron resonance CVD manner, the deposition pressure ranges from 1 mTorr to 30 mTorr.

8. The method according to claim 7, wherein during operation of the high density plasma electron cyclotron resonance CVD manner, the deposition pressure ranges from 5 mTorr to 25 mTorr.

9. The method according to claim 8, wherein during operation of the high density plasma electron cyclotron resonance CVD manner, the deposition pressure ranges from 10 mTorr to 20 mTorr.

10. The method according to claim 1, wherein during operation of the high density plasma electron cyclotron resonance CVD manner, a gas doping ratio of H2:B2H6 is 10˜60:10˜50.

11. The method according to claim 10, wherein during operation of the high density plasma electron cyclotron resonance CVD manner, the gas doping ratio of H2:B2H6 is 20˜40:30˜50.

12. The method according to claim 1, wherein the thickness of the first doped semiconductor layer ranges from 5 nm to 50 nm.

13. The method according to claim 12, wherein the thickness of the first doped semiconductor layer ranges from 10 nm to 35 nm.

14. The method according to claim 1, wherein the first electrode is a transparent conductive layer, a metal conductive layer, or the transparent conductive layer and the metal conductive layer plated sequentially; wherein the transparent conductive layer is a zinc oxide layer, tin oxide layer or indium tin oxide (ITO) layer, and the metal conductive layer is a titanium/silver layer or an aluminum layer.

15. The method according to claim 1, wherein after the step (a01) of growing the first doped semiconductor layer and prior to the step (a02), a second doped semiconductor layer is grown on other surface of the crystalline silicon substrate opposite to the first doped semiconductor layer by using the high density plasma electron cyclotron resonance CVD in a condition of the temperature of the crystalline silicon substrate ranging from 50° C. to 250° C. , about 400 W of microwave power, deposition pressure below 50 mTorr, about 20 sccm of argon flow rate, about 15 sccm of hydrogen flow rate, about 1 sccm of SiH₄ flow rate, and 2% phosphine flow rate ranging from about 5 sccm to 15 sccm, and the second doped semiconductor layer has a thickness ranging from 5 nm to 80 nm and about 1.12 eV of bandgap.

16. The method according to claim 15, wherein after the second doped semiconductor layer is grown and prior to the step (a02), a second anti-reflection layer is formed on a surface of the second doped semiconductor layer.

17. The method according to claim 15, wherein in the step (a02), the first electrode is formed on a surface of the first doped semiconductor layer, and a second electrode is formed on the second doped semiconductor layer.

18. The method according to claim 17, wherein the second electrode is the transparent conductive layer, the metal conductive layer or the transparent conductive layer and the metal conductive layer plated sequentially;
wherein the transparent conductive layer is the zinc oxide layer, the tin oxide layer or the indium tin oxide (ITO) layer, and the metal conductive layer is the titanium/silver layer or the aluminum layer.

19. The method according to claim 15, wherein the thickness of the second doped semiconductor layer ranges from 5 nm to 50 nm.

20. The method according to claim 19, wherein the thickness of the second doped semiconductor layer ranges from 10 nm to 35 nm.

21. The method according to claim 15, wherein the first doped semiconductor layer is an N-type epitaxy silicon layer or a P-type epitaxy silicon layer, and the second doped semiconductor layer is a P-type epitaxy silicon layer or N-type epitaxy silicon layer relatively, and the first doped semiconductor layer is a doped epitaxy back surface field (BSF) layer.
